(19) United States
(12) Patent Application Publication
(10) Pub. No.: US 2007/0164784 A1
(43) Pub. Date: Jul. 19, 2007

(54) Modular I/O bank architecture

(75) Inventors: Sanjay Charagulla, San Jose, CA (US); Ali Burney, Fremont, CA (US)

Correspondence Address: TOWNSEND AND TOWNSEND AND CREW LLP/ 015114, TWO EMBARCADERO CENTER, 8TH FLOOR, SAN FRANCISCO, CA, 94111-3834, US

(73) Assignee: Altera Corporation, San Jose, CA (US)

(21) Appl. No.: 11/337,046

(22) Filed: Jan. 19, 2006

(51) Int. Cl. H03K 19/177

(52) U.S. Cl. 326/41

(57) ABSTRACT

A programmable device I/O architecture allows for a variable number of I/O banks. Each I/O bank is of an I/O bank type. Each I/O bank type has a fixed number of I/O pins. I/O banks of the same I/O type are compatible within the same programmable device and between different types of programmable devices. The number of I/O pins for each I/O bank type is selected so that each of a set of interfaces can be implemented efficiently using I/O banks of at least one I/O bank type. The largest size I/O bank type and intermediate size I/O bank types are adapted to be a compatible supersets of every smaller I/O bank type. The ratio between data pins and support pins in each I/O bank type is the same. Support pins are regularly distributed between data pins in each I/O bank type.

### BACKGROUND OF THE INVENTION

The present invention relates to the field of programmable devices, and the systems and methods for programming the same. Programmable devices, such as FPGAs, typically includes thousands of programmable logic cells that use combinations of logic gates and/or look-up tables to perform a logic operation. Programmable devices also include a number of functional blocks having specialized logic devices adapted to specific logic operations, such as adders, multiply and accumulate circuits, phase-locked loops, and one or more embedded memory array blocks. The logic cells and functional blocks are interconnected with a configurable switching circuit. The configurable switching circuit selectively routes connections between the logic cells and functional blocks. By configuring the combination of logic cells, functional blocks, and the switching circuit, a programmable device can be adapted to perform virtually any type of information processing function.

Programmable devices include one or more input/output (I/O) banks for communication with external devices, such as memory devices, network interfaces, data buses and data bus controllers, microprocessors, other programmable devices, ASICs, or any other type of electronic device. Each I/O bank is connected with a number of conductive I/O pins, balls, or other electrical connectors in the programmable device chip package. An I/O bank includes logic for sending and receiving data signals, control signals, clock signals, power and ground signals, or any other type of signal used in conjunction with communications between the programmable device and an external device.

The I/O banks of a programmable device include logic, amplifiers, filters, and other circuits that together can be configured to provide one or more standard interfaces between the programmable device and external devices. Additionally, the I/O banks of a programmable device can be configured to provide custom or proprietary interfaces if required by a particular application.

Typically, a wide range of different programmable devices are designed as part of a programmable device family. The programmable devices within a device family typically have similar architectures but may differ in chip package size and type, the number of I/O pins, the number of logic cells, the number and type of functional blocks and other specialized logic blocks, and/or other characteristics.

In prior programmable device families, the programmable device architecture supports only a fixed number of I/O banks. As a result, programmable devices within the device family may have different amounts of I/O pins per I/O bank. For example, if a programmable device architecture supports 8 I/O banks, a small programmable device within the device family may only have 20 I/O pins per I/O bank, for a total of 160 I/O pins for the programmable device. In contrast, an example large programmable device within the device family may have 70 I/O pins per I/O bank, for a total of 560 I/O pins for the programmable device.

The use of a fixed number of I/O banks and a variable number of I/O pins per I/O bank in a programmable device architecture presents a number of problems. First, most I/O banks can only be configured to support a one interface at a time. As the number of I/O pins per I/O bank increases, any I/O pins not needed for the supported interface are left unused. The unused I/O pins from one or more I/O banks cannot be aggregated to support an additional interface. Thus, as the number of I/O pins per I/O bank increases, the percentage of I/O pins utilized typically decreases. This often forces designers to use programmable devices with even more I/O pins to ensure that there are sufficient I/O pins available to support the required interfaces, which further increases the costs of implementing a design. Additionally, these restrictions on I/O pin usage limit the designers' flexibility in circuit board layout.

Vertical migration is another problem arising from prior programmable device architectures that use of a fixed number of I/O banks and a variable number of I/O pins per bank. Often, designers will develop an initial design for a particular size programmable device within a device family. Subsequent revisions or improvements to the design may require additional programmable device resources. Designers would like to be able to implement the revised design using a larger size programmable device within the same device family without substantial reengineering and testing costs.

However, prior programmable device architectures having a fixed number of I/O banks and a variable number of I/O pins per bank often require substantial reengineering for vertical migration. For example, because the number of I/O pins per I/O bank often increases for a larger devices, the I/O banks of the larger device may not support the same I/O pin assignments as the corresponding I/O banks in the smaller device. Thus, designers must reengineer the device as well as associated circuit boards to account for these differences.

Noise, clock skew, and signal reflection are other problems arising in vertical migration that are caused by the use of a fixed number of I/O banks and a variable number of I/O pins per bank. As the number of pins per I/O bank increase, the total number of active switches and other components associated with I/O pins increases, thereby increasing the amount of noise and signal reflections introduced. Similarly, I/O banks with more I/O pins will have greater amounts of clock skew than smaller I/O banks. Thus, when a design is migrated from a smaller programmable device to a larger programmable device, designers must work to overcome the additional noise, signal reflections, and clock skew introduced by the use of I/O banks with additional I/O pins.

It is therefore desirable for a programmable device architecture to overcome the difficulties normally associated with a fixed number of I/O banks having variable numbers of I/O pins. It is desirable for the programmable device architecture to allow for efficient I/O pin utilization regardless of the total number of I/O pins. It is further desirable for the programmable device architecture to facilitate vertical migration to larger programmable devices while reducing the required reengineering effort. It is also desirable for the I/O banks to have improved performance as compared with I/O banks of prior programmable device architectures.

### BRIEF SUMMARY OF THE INVENTION

In an embodiment, a programmable device I/O architecture allows for a variable number of I/O banks. Each I/O bank is of an I/O bank type. Each I/O bank type has a fixed number of I/O pins. I/O banks of the same I/O type are compatible within the same programmable device and between different types of programmable devices. The number of I/O pins for each I/O bank type is selected so that each of a set of interfaces can be implemented efficiently using I/O banks of at least one I/O bank type. In a further embodiment, the largest size I/O bank type and intermediate size I/O bank types are adapted to be a compatible supersets of every smaller I/O bank type. In another embodiment, the ratio between data pins and support pins in each I/O bank type is the same. In a further embodiment, support pins are regularly distributed between data pins in each I/O bank type.

In an embodiment, a programmable device comprises a programmable device core, a first set of I/O banks of a first type, and a second set of I/O banks of a second type. Each of the I/O banks of the second type is a compatible superset of an I/O bank of the first type. In an embodiment, each of the I/O banks of the first type has a first fixed number of pins and each of the I/O banks of the second type has a second fixed number of pins. The first and second fixed numbers of pins are selected so as to efficiently implement a set of interfaces.

In a further embodiment, each of the I/O banks of the first type and of the second type includes data pins and support pins. The ratio of data pins to at least a portion of the support pins in each one of the I/O banks of the first type may be the same as a ratio of data pins to at least a portion of the support pins in each one of the I/O banks of the second type. The portion of the support pins may include ground pins, power pins, and/or clock pins.

In another embodiment, at least a portion of the support pins of each I/O bank of the first type are distributed within its respective I/O bank at a regular interval. In a further embodiment, at least a portion of the support pins of each I/O bank of the second set are distributed within its respective I/O bank at the same regular interval.

In an additional embodiment, the first and second types of I/O banks have similar performance characteristics, such as signal to noise ratios and/or clock skew.

In yet another embodiment, each I/O bank of the first set of I/O banks is functionally identical to an I/O bank of a second programmable device in a family of programmable devices. The second programmable device has different specifications than the programmable device. In still another embodiment, each I/O bank of the second set of I/O banks includes a portion functionally identical to an I/O bank of a second programmable device in a family of programmable devices. The second programmable device has different specifications than the programmable device.

### BRIEF DESCRIPTION OF THE DRAWINGS

The invention will be described with reference to the drawings, in which:

FIG. 1 illustrates a programmable device and I/O bank architecture according to an embodiment of the invention;

FIG. 2 illustrates a family of programmable devices according to an embodiment of the invention;

FIG. 3 illustrates I/O pin compatibility between I/O banks according to an embodiment of the invention; and

FIG. 4 illustrates a programmable device suitable for use with an embodiment of the invention.

### DETAILED DESCRIPTION OF THE INVENTION

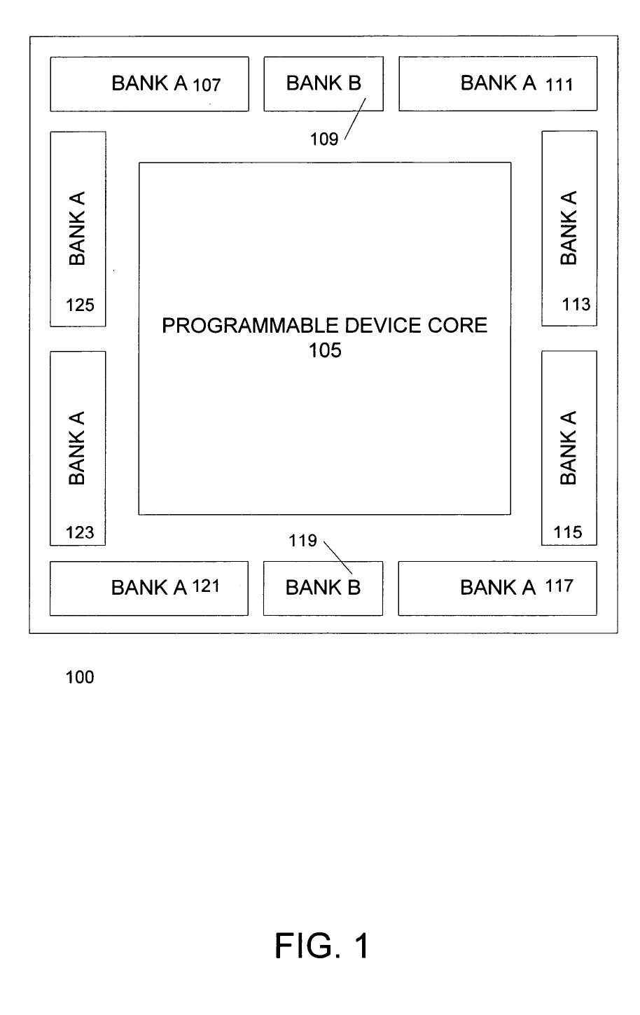

FIG. 1 illustrates a programmable device and I/O bank architecture 100 according to an embodiment of the invention. Device architecture 100 includes a programmable device core 105. Programmable device core 105 includes programmable device components such as logic cells, functional blocks, memory units, and a configurable switching circuit.

Device architecture 100 includes a plurality of I/O banks, such as I/O banks 107, 109, 111, 113, 115, 117, 119, 121, 123, and 125. In an embodiment, device architecture 100 allows for any number of I/O banks.

In an embodiment, the plurality of I/O banks belong to a limited number of I/O bank types. For example, I/O banks 107, 111, 113, 115, 117, 121, 123, and 125 are of I/O bank type A. I/O banks 109 and 119 belong to I/O bank type B. Each I/O bank type specifies the number of I/O pins and other attributes for its member I/O banks. For example, type A I/O banks may have 60 I/O pins and type B I/O banks may have 36 I/O pins. The number of I/O banks types is not limited to two types, and many common implementations of device architecture 100 may include four or more different I/O types.

The number of I/O pins for each I/O bank type can be specified based on the common interface types to be implemented by the I/O banks. If necessary, two or more I/O banks can be aggregated to implement a single interface. Table 1 lists the number of I/O banks required to implement several common standard interfaces based on the number of I/O pins available in the bank. These interfaces are provided for the purposes of illustration, and other interfaces may be implemented with one or more I/O banks, including memory interfaces, bus interfaces, and general purpose digital communications interfaces. Table 1 and similar tables can be used to help select an optimal number of I/O pins for each I/O bank type based on the anticipated interface applications for device architecture 100.

TABLE 1
I/O Banks Required to Implement Interfaces

| | Interface | | | | | | | |
|---|---|---|---|---|---|---|---|---|
| Bank | DDR 36 | DDR 72 | QDR 36 | QDR 72 | SPI4.2 | RLII 36 | RLII 72 | PCI 64 |
| Size | 72 | 118 | 64 | 100 | 86 | 73 | 113 | 91 |
| 22 | 4 | 6 | 3 | 5 | 4 | 4 | 6 | 5 |
| 23 | 4 | 6 | 3 | 5 | 4 | 4 | 5 | 4 |
| 24 | 3 | 5 | 3 | 5 | 4 | 4 | 5 | 4 |
| 25 | 3 | 5 | 3 | 4 | 4 | 3 | 5 | 4 |
| 26 | 3 | 5 | 3 | 4 | 4 | 3 | 5 | 4 |
| 27 | 3 | 5 | 3 | 4 | 4 | 3 | 5 | 4 |
| 28 | 3 | 5 | 3 | 4 | 4 | 3 | 5 | 4 |
| 29 | 3 | 5 | 3 | 4 | 3 | 3 | 4 | 4 |
| 30 | 3 | 4 | 3 | 4 | 3 | 3 | 4 | 4 |
| 31 | 3 | 4 | 3 | 4 | 3 | 3 | 4 | 3 |
| 32 | 3 | 4 | 2 | 4 | 3 | 3 | 4 | 3 |
| 33 | 3 | 4 | 2 | 4 | 3 | 3 | 4 | 3 |
| 34 | 3 | 4 | 2 | 3 | 3 | 3 | 4 | 3 |
| 35 | 3 | 4 | 2 | 3 | 3 | 3 | 4 | 3 |
| 36 | 2 | 4 | 2 | 3 | 3 | 3 | 4 | 3 |
| 37 | 2 | 4 | 2 | 3 | 3 | 2 | 4 | 3 |
| 38 | 2 | 4 | 2 | 3 | 3 | 2 | 3 | 3 |
| 39 | 2 | 4 | 2 | 3 | 3 | 2 | 3 | 3 |
| 40 | 2 | 3 | 2 | 3 | 3 | 2 | 3 | 3 |
| 41 | 2 | 3 | 2 | 3 | 3 | 2 | 3 | 3 |
| 42 | 2 | 3 | 2 | 3 | 3 | 2 | 3 | 3 |
| 43 | 2 | 3 | 2 | 3 | 2 | 2 | 3 | 3 |
| 44 | 2 | 3 | 2 | 3 | 2 | 2 | 3 | 3 |
| 45 | 2 | 3 | 2 | 3 | 2 | 2 | 3 | 3 |
| 46 | 2 | 3 | 2 | 3 | 2 | 2 | 3 | 2 |
| 47 | 2 | 3 | 2 | 3 | 2 | 2 | 3 | 2 |
| 48 | 2 | 3 | 2 | 3 | 2 | 2 | 3 | 2 |
| 49 | 2 | 3 | 2 | 3 | 2 | 2 | 3 | 2 |
| 50 | 2 | 3 | 2 | 2 | 2 | 2 | 3 | 2 |
| 51 | 2 | 3 | 2 | 2 | 2 | 2 | 3 | 2 |
| 52 | 2 | 3 | 2 | 2 | 2 | 2 | 3 | 2 |
| 53 | 2 | 3 | 2 | 2 | 2 | 2 | 3 | 2 |
| 54 | 2 | 3 | 2 | 2 | 2 | 2 | 3 | 2 |
| 55 | 2 | 3 | 2 | 2 | 2 | 2 | 3 | 2 |
| 56 | 2 | 3 | 2 | 2 | 2 | 2 | 3 | 2 |
| 57 | 2 | 3 | 2 | 2 | 2 | 2 | 2 | 2 |
| 58 | 2 | 3 | 2 | 2 | 2 | 2 | 2 | 2 |
| 59 | 2 | 2 | 2 | 2 | 2 | 2 | 2 | 2 |
| 60 | 2 | 2 | 2 | 2 | 2 | 2 | 2 | 2 |
| 61 | 2 | 2 | 2 | 2 | 2 | 2 | 2 | 2 |
| 62 | 2 | 2 | 2 | 2 | 2 | 2 | 2 | 2 |

Additionally, an I/O pin efficiency can be determined based on the number of I/O in each I/O bank type. The I/O pin efficiency is number of I/O pins utilized in one or I/O banks to implement an interface compared with the total number of I/O pins available in these I/O banks. The number of I/O bank types and the number of I/O pins in each I/O bank type can be selected to maximize I/O bank pin efficiency for the anticipated interface applications of device architecture 100. Table 2 illustrates an example I/O pin efficiency determination for two I/O bank types having 36 and 54 I/O pins, respectively.

TABLE 2
Example I/O Pin Efficiency for Two Different I/O Bank Types

| | | 36-bit Bank | | | | 54-bit Bank | | | |
|---|---|---|---|---|---|---|---|---|---|
| | Req | #36b | I/Os | Left | Efficiency | #54b | I/Os | Left | Efficiency |
| Interface | I/O's | Banks | Used | Over | (%) | Banks | Used | Over | (%) |
| DDR-2 36-bit (×8) | 72 | 2 | 72 | 0 | 100% | 2 | 108 | 36 | 67% |
| DDR-2 72-bit (×8) | 122 | 4 | 144 | 22 | 85% | 3 | 162 | 40 | 75% |
| DDR-2 72-bit (×4) | 140 | 5 | 180 | 40 | 78% | 3 | 162 | 22 | 86% |
| QDR2 36-bit | 68 | 2 | 72 | 4 | 94% | 2 | 108 | 40 | 63% |
| QDR2 72-bit | 108 | 4 | 144 | 36 | 75% | 2 | 108 | 0 | 100% |
| SPI4.2 LVDS + LVTTL | 78 | 3 | 108 | 30 | 72% | 2 | 108 | 30 | 72% |
| SPI4.2 LVDS | [symbol] 5 | 3 | 108 | 22 | 80% | 2 | 108 | 22 | 80% |
| PCI-32 | 51 | 2 | 72 | 21 | 71% | 1 | 54 | 3 | 94% |
| PCI-64 | 91 | 3 | 108 | 17 | 84% | 2 | 108 | 17 | 84% |

In the example of table 2, each example interface type can be implemented with a relatively high I/O pin efficiency in at least one of I/O bank types. For example, a PCI-32 interface implemented with two 36 I/O pin I/O banks has an I/O pin efficiency of 71%, while the PCI-32 interface implemented with one 54 I/O pin I/O bank has an I/O pin efficiency of 94%.

In an embodiment, I/O banks of the same I/O bank type have similar attributes and capabilities, regardless of their locations within a particular device. For example, I/O banks 109 and 119, which are both of type B, can have similar numbers of I/O pins, power and grounding characteristics, signal to noise ratios, reflection characteristics, timing characteristics, and clock skews. Because of the similarities of I/O banks having the same type, designers can utilize different I/O banks of the same type interchangeably, which provides increased flexibility in circuit board layout.

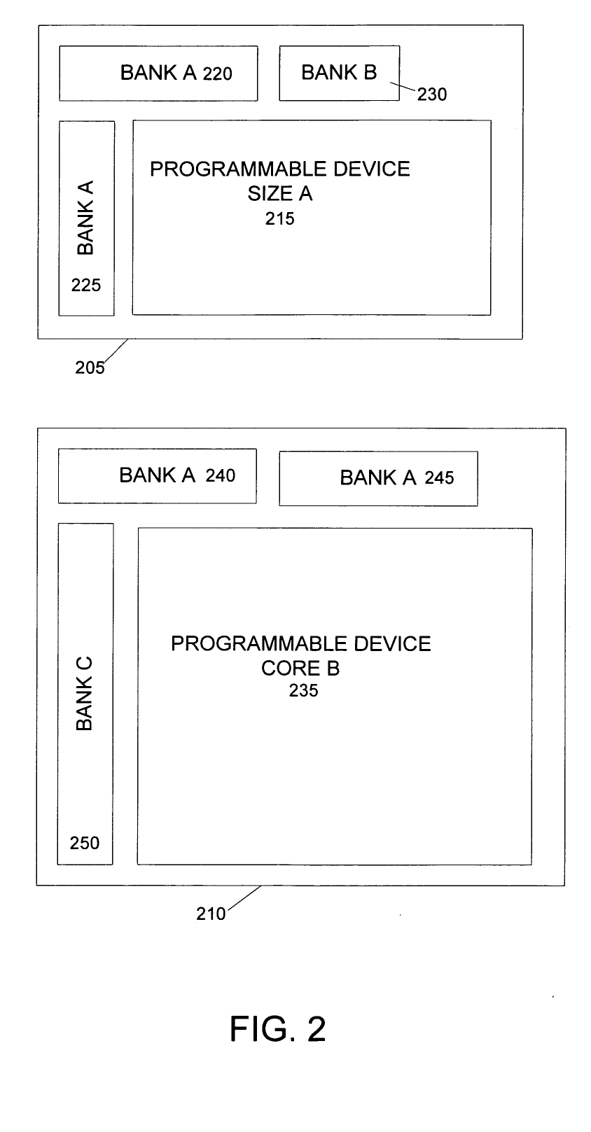

In further embodiments, I/O banks of the same type have similar attributes for different devices within the same device family, which facilitates vertical migration. FIG. 2 illustrates a family 200 of programmable devices according to an embodiment of the invention. Device family 200 includes programmable devices 205 and 210. Programmable device 205 includes programmable device core 215, which includes programmable device components such as logic cells, functional blocks, memory units, and a configurable switching circuit. Programmable device 205 includes two I/O banks 220 and 225 of a first I/O bank type, referred to as type A, and one I/O bank 230 of a second I/O bank type, referred to as type B.

Similarly, programmable device 210 includes a programmable device core 235, two I/O banks 240 and 255 of type A, and one I/O bank 250 of a third I/O bank type, referred to as type C.

In an embodiment of the device family 200, I/O banks of the same type have similar I/O pin counts, power and grounding characteristics, signal to noise ratios, reflection and impedance characteristics, timing characteristics, and clock skews. For example, I/O banks 220 and 240 in programmable devices 205 and 210, respectively, have similar characteristics. Thus, a design using I/O bank 220 and initially targeted for programmable device 205 can be migrated to programmable device 210 and corresponding I/O bank 240 with minimal reengineering effort.

In a further embodiment, I/O banks of different types can be compatible. For example, an I/O bank of type C can be a superset of an I/O bank of type A. In this embodiment, I/O bank 250 can have more I/O pins than I/O bank 225. However, a portion of the I/O pins of I/O bank 250 will be compatible with the I/O pins of I/O bank 225. In still a further embodiment, the other characteristics of two or more I/O bank types, such as power, voltage, grounding, impedance, signal to noise ratios, timing characteristics, clock skew and any other attributes aside from the number of I/O pins, are similar. Thus, a design using I/O bank 225 and initially targeted for programmable device 205 can be migrated to programmable device 210 and larger but compatible I/O bank 250. Similarly, I/O banks of type A can be a compatible superset of I/O banks of type B, so that designs using I/O bank 230 of programmable device 205 can be migrated to larger but compatible I/O bank 245 of programmable device 210.

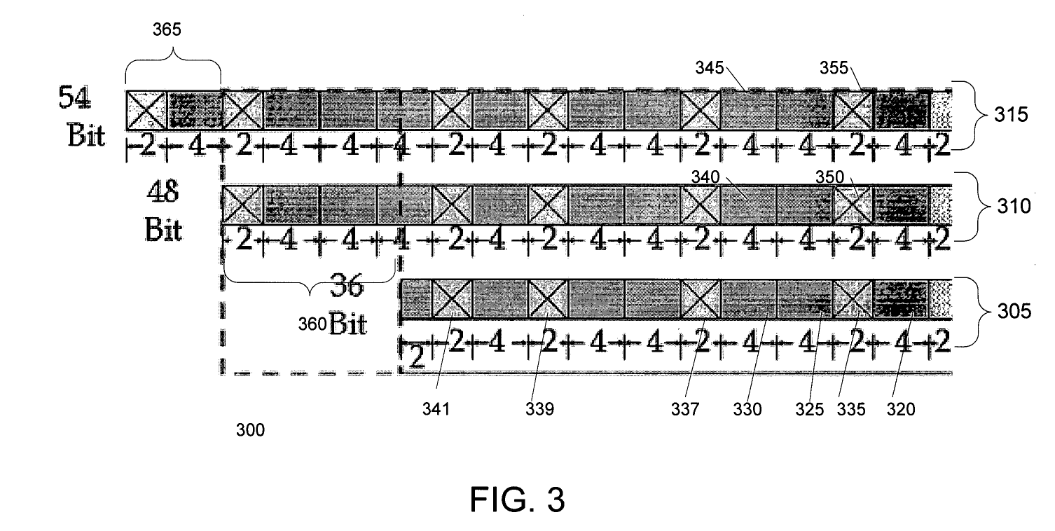

FIG. 3 illustrates I/O pin compatibility between I/O banks according to an embodiment of the invention. The functions of I/O pins for I/O bank types 305, 310, 315. I/O bank type 305 includes 36 I/O pins for carrying data signals and power and ground connections. I/O bank 305 can include additional pins not shown in FIG. 3 for clock signals or other connections.

In an embodiment, I/O pins are arranged in groups of two or four pins. For example, I/O bank type 305 include groups of four data pins, such as groups 320, 325, and 330. I/O bank type also includes groups of two power and ground pins, such as groups 335, 337, 339, and 341. In an embodiment, the groups of power and ground pins are distributed regularly throughout the I/O bank. For example, every group of power and ground pins, such as group 335, is adjacent to at most eight data pins, such as data pin groups 320 and 325. This distribution of power and ground pin between data pins reduces the overall signal to noise ratios and helps maintain constant signal to noise ratios regardless of the total number of I/O pins in the I/O bank type, which facilitates vertical migration to larger I/O banks.

In an embodiment, each group of I/O pins in I/O bank type 305 has a corresponding group in I/O bank type 310, which has 48 I/O pins, and I/O bank type 315, which has 54 I/O pins. For example, I/O data pin group 330 corresponds with data pin group 340 in I/O bank type 310 and with data pin group 345 in I/O bank type 315. Similarly, power and ground pin group 335 in I/O bank type 305 corresponds with group 350 in I/O bank type 310 and group 355 in I/O bank type 315.

As discussed above, larger I/O bank types can be supersets of smaller I/O bank types to maintain compatibility. In an embodiment, I/O bank type 310 includes all of the I/O pins of I/O bank 305 in corresponding locations. Additional I/O pins in I/O bank type 310, such as additional I/O pins 360, are appended at the end of the I/O bank. Similarly, additional I/O pins 360 are appended to the end of I/O bank type 315, which makes this I/O bank type compatible with I/O bank types 310 and 305.

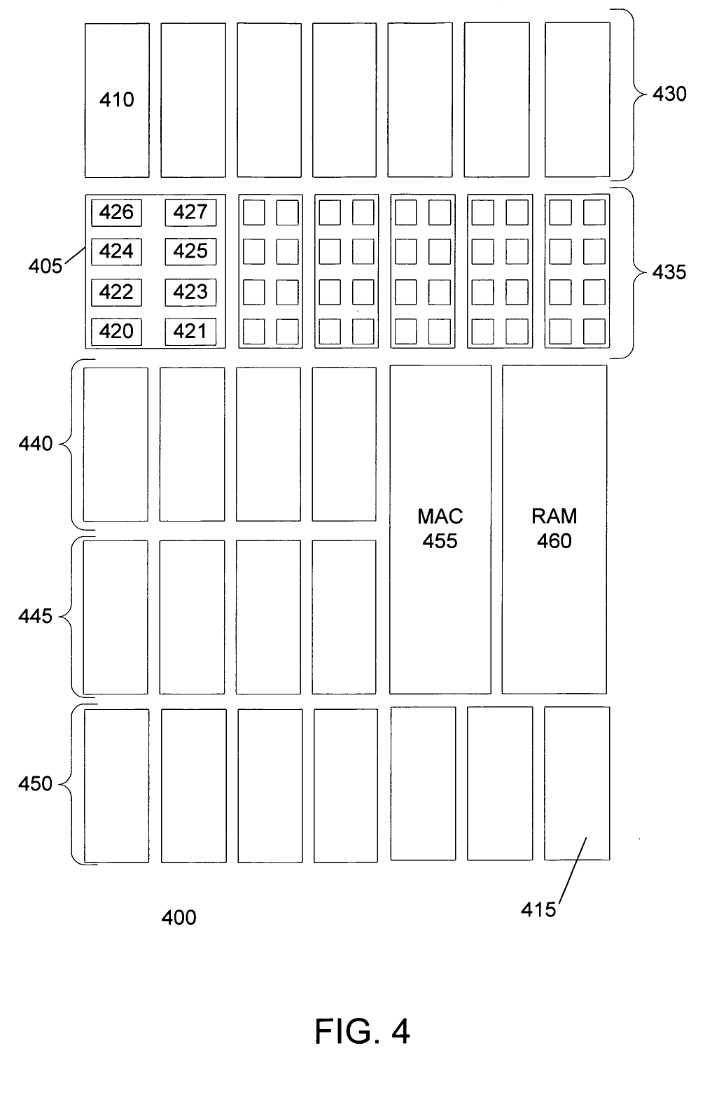

FIG. 4 illustrates a programmable device 400 suitable for use with an embodiment of the invention. Programmable device 400 includes a number of logic array blocks (LABs), such as LABs 405, 410, 415. Each LAB includes a number of programmable logic cells using logic gates and/or look-up tables to perform logic operations, as well as registers to store and retrieve data. LAB 405 illustrates in detail logic cells 420, 421, 422, 423, 424, 425, 426, and 427. Logic cells are omitted from other LABs in FIG. 4 for clarity. The LABs of device 400 are arranged into rows 430, 435, 440, 445, and 450. In an embodiment, the arrangement of logic cells within a LAB and of LABs within rows provides a hierarchical system of configurable connections of a programmable switching circuit, in which connections between logic cells within a LAB, between cells in different LABs in the same row, and between cell in LABs in different rows require progressively more resources and operate less efficiently.

In addition to logic cells arranged in LABs, programmable device 400 also include specialized functional blocks, such as multiply and accumulate block (MAC) 455 and random access memory block (RAM) 460. The configuration of the programmable device is specified at least in part by configuration data stored in configuration memory 475. The configuration data can include values for lookup tables defining the functions of logic cells; values of control signals for multiplexers and other switching devices used by the configurable switching circuit to route signals between inputs, outputs, logic cells, and functional blocks; and values specifying other aspects of the configuration of the programmable device, such as modes of operation of the programmable device and its assorted functional blocks and logic cells. Although the configuration memory 475 is shown in FIG. 4 as a monolithic unit, in some programmable devices, configuration memory 475 is scattered all over the programmable device. In these types of programmable devices, portions of the configuration memory can lie within the logic cells, functional blocks, and configurable switching circuit of the programmable device.

For clarity, the portion of the programmable device 400 shown in FIG. 4 only includes a small number of logic cells, LABs, and functional blocks. Typical programmable devices will include thousands or tens of thousands of these elements.

Further embodiments can be envisioned to one of ordinary skill in the art after reading the attached documents. For example, although the invention has been discussed with reference to programmable devices, it is equally applicable to standard or structured ASICs, gate arrays, and general digital logic devices. In other embodiments, combinations or sub-combinations of the above disclosed invention can be advantageously made. The block diagrams of the architecture and flow charts are grouped for ease of understanding. However it should be understood that combinations of blocks, additions of new blocks, re-arrangement of blocks, and the like are contemplated in alternative embodiments of the present invention.

The specification and drawings are, accordingly, to be regarded in an illustrative rather than a restrictive sense. It will, however, be evident that various modifications and changes may be made thereunto without departing from the broader spirit and scope of the invention as set forth in the claims.

What is claimed is:

1. A programmable device in a programmable device family comprising a plurality of programmable devices, the programmable device comprising:
a programmable device core;
a first I/O bank comprising a first set of pins, wherein the first set of pins includes data pins and support pins; and
a second I/O bank comprising a second set of pins, wherein a first portion of the pins of the first I/O bank has a one-to-one correspondence with the second set of pins of the second I/O bank, and wherein a remaining portion of the first set of pins does not have any correspondence with the second set of pins of the second I/O banks.

2. The programmable device of claim 1, wherein the support pins include power and ground pins.

3. The programmable device of claim 2, wherein a ratio between the number of power and ground pins and the number of data pins is fixed.

4. The programmable device of claim 3, wherein the power and ground pins are interleaved with the data pins.

5. The programmable device of claim 3, wherein the second set of pins of the second I/O bank includes data pins and support pins, and wherein a ratio between the number of power and ground pins and the number of data pins in the second set of pins is the same as the ratio between the number of power and ground pins and the number of data pins in the first set of pins.

6. The programmable device of claim 1, wherein the support pins include clock pins.

7. The programmable device of claim 1, wherein the second I/O bank is functionally identical to an I/O bank of a second programmable device in the family of programmable devices, wherein the second programmable device has different specifications than the programmable device.

8. The programmable device of claim 1, wherein the first I/O bank and the second I/O bank have similar performance characteristics.

9. The programmable device of claim 8, wherein the performance characteristics include a signal to noise ratio.

10. The programmable device of claim 8, wherein the performance characteristics include a clock skew.

11. The programmable device of claim 1, wherein the first I/O bank has a first fixed number of pins and the second I/O bank has a second fixed number of pins, such that the first and second fixed numbers of pins are adapted to efficiently implement a set of interfaces.

12. The programmable device of claim 11, further comprising a first plurality of I/O banks identical to the first I/O bank, wherein at least a portion of the set of interfaces can be implemented efficiently using at least one of the first plurality of I/O banks and the first I/O bank.

13. The programmable device of claim 11, further comprising a first plurality of I/O banks identical to the second I/O bank, wherein at least a portion of the set of interfaces can be implemented efficiently using at least one of the first plurality of I/O banks and the second I/O bank.

14. The programmable device of claim 11, wherein the set of interfaces includes a memory interface.

15. The programmable device of claim 11, wherein the set of interfaces includes a bus interface.

16. The programmable device of claim 11, wherein the set of interfaces includes a general-purpose digital communications interface.

17. A programmable device comprising:
a programmable device core;
a first plurality of I/O banks of a first type;
a second plurality of I/O banks of a second type; wherein each of the I/O banks of the second type is a compatible superset of an I/O bank of the first type.

18. The programmable device of claim 17, wherein each of the I/O banks of the first type and of the second type includes data pins and support pins.

19. The programmable device of claim 18, wherein a ratio of data pins to at least a portion of the support pins in each of the plurality I/O banks of the first type is the same as a ratio of data pins to at least a portion of the support pins in each of the plurality I/O banks of the second type.

20. The programmable device of claim 19, wherein the portion of the support pins includes ground pins.

21. The programmable device of claim 19, wherein the portion of the support pins includes power pins.

22. The programmable device of claim 19, wherein the portion of the support pins includes clock pins.

23. The programmable device of claim 18, wherein at least a portion of the support pins of each I/O bank of the first plurality are distributed within its respective I/O bank at a regular interval.

24. The programmable device of claim 23, wherein at least a portion of the support pins of each I/O bank of the second plurality are distributed within its respective I/O bank at the regular interval.

25. The programmable device of claim 17, wherein the first and second plurality of I/O banks have similar performance characteristics.

26. The programmable device of claim 25, the performance characteristics include a signal to noise ratio.

27. The programmable device of claim 25, wherein the performance characteristics include a clock skew.

28. The programmable device of claim 17, wherein each I/O bank of the first plurality of I/O banks is functionally identical to an I/O bank of a second programmable device in a family of programmable devices, wherein the second programmable device has different specifications than the programmable device.

29. The programmable device of claim 17, wherein each I/O bank of the second plurality of I/O banks includes a portion functionally identical to an I/O bank of a second programmable device in a family of programmable devices, wherein the second programmable device has different specifications than the programmable device.

30. The programmable device of claim 17, wherein the each of the first plurality of I/O banks has a first fixed number of pins and each of the second plurality of I/O banks has a second fixed number of pins, such that the first and second fixed numbers of pins are adapted to efficiently implement a set of interfaces.
